(19) United States
(12) Patent Application Publication
(10) Pub. No.: US 2025/0284463 A1
(43) Pub. Date: Sep. 11, 2025

(54) METHOD FOR REAL-TIME SYNTHESIZING AN ARBITRARY DISTRIBUTION NOISE SIGNAL BASED ON GAUSSIAN MIXTURE MODEL

(71) Applicant: UNIVERSITY OF ELECTRONIC SCIENCE AND TECHNOLOGY OF CHINA, Chengdu (CN)

(72) Inventors: Bo XU, Chengdu (CN); Yuhua CHENG, Chengdu (CN); Kai CHEN, Chengdu (CN); Jia ZHAO, Chengdu (CN); Wenjian MA, Chengdu (CN); Yifan WANG, Chengdu (CN); Gen QIU, Chengdu (CN); Zhen LIU, Chengdu (CN)

(73) Assignee: UNIVERSITY OF ELECTRONIC SCIENCE AND TECHNOLOGY OF CHINA, Chengdu (CN)

(21) Appl. No.: 19/217,132

(22) Filed: May 23, 2025

(30) Foreign Application Priority Data
Jun. 18, 2024 (CN) 202410784424.5

(51) Int. Cl. G06F 7/58

(52) U.S. Cl. CPC G06F 7/582

(57) ABSTRACT

A method for synthesizing arbitrary distribution noise signal includes two parts. An upper computer fits H given distribution function ƒ(x) to obtain H pluralities of K pairs of means μₖ^{h} and variances σₖ^{h}, by using Expectation Maximization algorithm based on a weakened Gaussian Mixture Model. An FPGA stores H pluralities of K pairs of means μₖ^{h} and variances σₖ^{h} into RAM, function values that box-muller transformation needs into ROM 1 and ROM 2, then read out two function values and multiply them to obtain random number xₙ, means μₖ^{h} and variances σₖ^{h} are read out from RAM to synthesizing k^{th} Gaussian noise signal yₖₙ^{h}, after amplitude limitation and normalization, obtained analogy signal is amplified Aₘₐₓ−Aₘᵢₙ times and set bias voltage to Aₘᵢₙ to obtain analogy noise signal with amplitude interval. An arbitrary distribution noise signal with specific distribution is outputted.

### FIELD OF THE INVENTION

This application claims priorities under the Paris Convention to Chinese Patent Application No. 202410784424.5, which is filed on Jun. 18, 2024, the entirety of which is hereby incorporated by reference for all purposes as if fully set forth herein.

The present invention relates to the field of generating noise, more particularly to a method for real-time synthesizing an arbitrary distribution noise signal based on Gaussian mixture model.

### BACKGROUND OF THE INVENTION

An arbitrary distribution noise signal typically is obtained through a digital to analog conversion (DAC) of arbitrary distribution random numbers, and the arbitrary distribution can be binomial distribution, Poisson distribution, exponential distribution and normal distribution etc. Therefore, how to generate various types of distribution numbers has become a must-be-addressed problem, when computer technology is applied to the field like simulation. Uniform distribution random numbers are usually used in generating arbitrary distribution random numbers. Based on uniform distribution random numbers, various types of distribution random numbers can be obtained through various transformations and mappings. In prior art, the various transformations and mappings include inverse function method, look-up table method and acceptance-rejection method etc.

### 1. Inverse Function Method

Inverse function method is based on inverse transform sampling theory, firstly, the inverse function of required probability distribution function of random numbers is calculated, then an inverse function computation module based on the inverse function is constructed on hardware, and then uniform distribution random numbers are inputted into the inverse function computation module to perform a real-time computation, the computing results are the required distribution random numbers.

The procedures are as follows:
(1). Generating a random number r, which is uniformly distributed in interval [0,1];
(2). Performing an inverse transformation on required probability distribution function F(x) to obtain its inverse function F⁻¹(z);
(3). Letting Z=F⁻¹(z), then Z is a random number, which obeys the required probability distribution function F(x);

So, if we know the inverse function F⁻¹(z) of a required probability distribution function F(x), a random number, which obeys the required probability distribution function F(x), can be generated from a random number r which is distributed in interval [0,1].

However, some of probability distribution functions are not elementary functions, obtaining their inverse functions is difficult. Moreover, constructing their inverse functions on hardware is very complex, perhaps even not being able to construct an inverse function computation module to perform inverse transformations for the uniform distribution random numbers. So, the inverse function can be obtained only by approximate fitting through some mathematical methods or storing the mapping of definition domain to value domain of the required probability distribution function by using large capacity memory. For the reason that real-time computation is needed for inputs, namely uniform random numbers, the output of required distribution random numbers is slower.

### 2. Acceptance-Rejection Method

The basic principles of Acceptance-rejection method are as follows: letting the given probability distribution function of random numbers is ƒ(x), U₁ is a random number uniformly distributed in intervals (0,a), U₂ is a random number uniformly distributed in interval (0,b), if U₂<ƒ(U₁), then U₁ is outputted, otherwise U₁ is rejected, namely not outputted, thus the outputted random numbers satisfy the probability distribution function ƒ(x).

As shown in FIG. 1, if the area of shaded part is S, the output efficiency is η=S/(ab). Supposing the rate of generating uniformly distributed numbers is W(in), the average rate of outputting the random numbers with the given probability distribution function is W(out)=ηW(in).

In the process of realizing the acceptance-rejection method, a functional operation module based on a given probability distribution function ƒ(x) is constructed for calculating and outputting the random numbers in real time. For a complex probability distribution function ƒ(x), we can discretize and store it in a ROM (the stored in the ROM is probability distribution function ƒ(x), not the samples of generated random numbers through calculation), then addresses the probability distribution function ƒ(x), which is stored in the ROM, and reads out the value of ƒ(U₁), then judges whether it satisfies U₂<ƒ(U₁), if yes, then outputs U₁, otherwise, no random number is outputted at current clock.

The acceptance-rejection method can be easily realized, and the resource consumption of ROM is lower, only the discretized probability distribution function ƒ(x) is needed to be stored in ROM, however, the rate of generating random numbers is unstable, and a random number can be guaranteed to be outputted at each clock. Experiment shows that the acceptance rate of triangular distribution is 50%, the acceptance rate of standard normal distribution (4σ) is 31.33%.

### Look-Up Table Method

Look-up table method is commonly used to generate random numbers of given probability distribution function ƒ(x). As shown in FIG. 2, look-up table method is that firstly, a plurality of random numbers pre-calculated according to a given probability distribution function ƒ(x) is stored in a ROM of a FPGA, then a uniformly distributed random number x₁ is mapped to a physical address, and a random number x₂ satisfied with probability distribution function ƒ(x) is outputted according the physical address.

The implementation of Look-up table method is most intuitionistic and convenient, and no complex calculation is needed, the output speed is fast and stable. However, the output of random numbers depends on the prestored random numbers of given probability distribution function ƒ(x), randomness is weak, and the output error of lower probability numbers is large due to the limit of storage depth of ROM.

Generating random numbers of a probability distribution function shown in FIG. 3(a) is taken as example, the bit width of generated random numbers is set to 10 bits, the output error of lower probability numbers is set to 5%, the statistics of generated random numbers (pdf int rom) are shown in FIG. 3(b), the total of generated random numbers is 96301. When generating random numbers in FPGA, the ROM with storage depth of 90301 bits and bit width of 10 bits is needed (the total storage of ROM is 963010 bits) to store a table of random numbers, which is addressed later by uniformly distributed random numbers to output the random numbers which satisfies the given probability distribution function ƒ(x).

If the bit width of generated random numbers is set to 14 bits, the total storage of ROM is 1540265 bits, the resource consumption of ROM is extremely high, thus sacrificing the output error of lower probability numbers is an unavoidable choice. In addition, configuration parameters are large and inflexible.

### SUMMARY OF THE INVENTION

The present invention aims to overcome the deficiencies of the prior art, and provides a method for real-time synthesizing an arbitrary distribution noise signal based on Gaussian mixture model, so as to realize a stable generation of arbitrary distribution noise signal and improve its randomness, lower the output error of lower probability numbers, reduce the configuration parameters and enhance the flexibility of configuration.

To achieve these objectives, in accordance with the present invention, a method for real-time synthesizing an arbitrary distribution noise signal based on Gaussian mixture model is provided, comprising:
(1). obtaining H pluralities of K pairs of means and variances by an upper computer
1.1). taking a distribution function of arbitrary distribution numbers as a distribution function ƒ(x) to be fitted, and obtaining N observation data yⱼ=ƒ(xⱼ), j=1, 2, . . . , N, where xⱼ is a number uniformly taken from a value range of the distribution function ƒ(x);
1.2). initializing K pairs of means μₖ⁽⁰⁾ and variances σₖ⁽⁰⁾, k=1, 2, . . . , K, initializing iteration number i=1, and letting amplitude interval of a noise signal to be fitted is [Aₘᵢₙ, Aₘₐₓ], then K pairs of initial values of K arbitrary Gaussian distribution synthesis models are set as follows:

$$\{ \begin{matrix}a = \frac{{A}_{m ax} - {A}_{m i n}}{K} \\ {u}_{k}^{( 0 )} = {A}_{m i n} + ( k - 0.5 ) a \\ {σ}_{k}^{( 0 )} = 1\end{matrix}$$

1.3). calculating a probability γⱼₖ⁽ⁱ⁾ that the j^{th} observation data yⱼ at the i^{th} iteration is from the k^{th} arbitrary Gaussian distribution synthesis model:

$${γ}_{j k}^{( i )} = \frac{ϕ ( {y}_{j} \vert ( {μ}_{k}^{( i )} , {σ}_{k}^{( i )} ) )}{K {\sum }_{k = 1}^{K} ϕ ( {y}_{j} \vert ( {μ}_{k}^{( i )} {σ}_{k}^{( i )} ) )}$$

where ϕ (y|(μₖ⁽ⁱ⁾,σₖ⁽ⁱ⁾)) is a Gaussian distribution density function constructed by the k^{th} pair of mean μₖ⁽ⁱ⁾ and variance σₖ⁽ⁱ⁾ at the i^{th} iteration, ϕ (yⱼ|(μₖ⁽ⁱ⁾,σₖ⁽ⁱ⁾)) is a Gaussian distribution density of a Gaussian distribution density function ϕ (y|(μₖ⁽ⁱ⁾,σₖ⁽ⁱ⁾)) at y=y^{j};
1.4). calculating mean μₖ⁽ⁱ⁺¹⁾ and variance σₖ⁽ⁱ⁺¹⁾ at the i+1^{th} iteration:

$${μ}_{k}^{( i + 1 )} = \frac{{\sum }_{j = 1}^{N} {γ}_{j k}^{( i )} {y}_{j}}{{\sum }_{j = 1}^{N} {γ}_{j k}^{( i )}}$$

$${( {σ}_{k}^{( i + 1 )} )}^{2} = \frac{{\sum }_{j = 1}^{N} {{γ}_{j k}^{( i )} ( {y}_{j} - {μ}_{k}^{( i )} )}^{2}}{{\sum }_{j = 1}^{N} {γ}_{j k}^{( i )}}$$

1.5). judging whether μₖ⁽ⁱ⁺¹⁾−μₖ⁽ⁱ⁾ is less than a set threshold ε₁ and whether σₖ⁽ⁱ⁺¹⁾−σₖ⁽ⁱ⁾ is less than a set threshold ε₂, if yes, or iteration number i reaches a set upper limit, terminating iteration and taking mean μₖ⁽ⁱ⁺¹⁾ and variance σₖ⁽ⁱ⁺¹⁾ respectively as the mean μₖ and variance σₖ of the k^{th} arbitrary Gaussian distribution synthesis model, k=1, 2, . . . , K, otherwise, letting i=i+1 and returning to step 1.3);
1.6). replacing distribution function of arbitrary distribution numbers and repeating steps 1.1)˜1.5) to obtain H pluralities of K pairs of means and variances, where the k^{th} pair of means and variances in the h^{th} plurality are denoted by means μₖ^{h} and variances σₖ^{h}, h=1, 2, . . . , H, k=1, 2, . . . , K, then sending the H pluralities of K pairs of means and variances to a FPGA;
(2). outputting an arbitrary distribution noise signal by a FPGA
2.1). in the FPGA, storing the function values that box-muller transformation needs by ROM 1 and ROM 2: ROM 1 is used to store the corresponding function values of cos(22πu₁) or sin(2πu₁), its address bit-width is N₁, its data bit-width is 64, its data type is double-precision floating point, and u₁ is:

$${u}_{1} = \frac{{b}_{1}}{{2}^{N} - {b}_{1}} , {b}_{1} = 0 , 1 , … , {2}^{N} - 1$$

where b₁ is an address;

ROM 2 is used to store the corresponding function values of \sqrt{−2 ln(u₂)}, its address bit-width is N₂, its data bit-width is 64, its data type is double-precision floating point, and u₂ is:

$${u}_{2} = 2 π \frac{{b}_{2}}{{2}^{{N}_{2}}} , {b}_{2} = 1 , 2 , … {2}^{{N}_{2}}$$

where b₂ is an address;

storing the H pluralities of K pairs of means μₖ^{h} and variances σₖ^{h}, h=1, 2, . . . , H, k=1, 2, . . . , K, obtained by the upper computer in a RAM: simultaneously caching H pluralities of parameters of different Gaussian mixture models, each plurality of parameters corresponds a Gaussian mixture model, which comprise means μₖ and variances σₖ, k=1, 2, . . . , K of K arbitrary Gaussian distribution synthesis models and are used to generate a different arbitrary distribution noise signal, where the storage depth of the RAM is H×K, the data bit-width is 128, each data consists of a mean μₖ^{h} and a variance μₖ^{h} with 64 bits respectively;
2.2). synthesizing the k^{th} Gaussian noise signal
firstly, generating N₁+N₂ bits uniformly distributed random numbers by taking a chaos model as a digital entropy source, where the n number is denoted by rₙ, n is a serial number, addressing ROM 1 by taking the high N₁ bits as address b₁ to obtain corresponding function value of cos(2πu₁) or sin(2πu₁), addressing ROM 2 by taking the low N₂ bits as address b₂ to obtain corresponding function value of \sqrt{−2 ln(u₂)}, where address bit-width N₁ of ROM 1 and address bit-width N₂ of ROM 2 satisfy the following constraints:

$$\{ \begin{matrix}{N}_{1} \geq ⌈ \frac{{N}_{DAC}}{2} ⌉ \\ {N}_{2} \geq ⌈ \frac{{N}_{DAC}}{2} ⌉\end{matrix}$$

where N_{DAC} is the bit-width of a DAC;
multiplying the function value of cos(2πu₁) or sin(2πu₁) by the function value of \sqrt{−2 ln(u₂)} to obtain a random number, which obeys standard Gaussian distribution and is denoted by xₙ;
then reading out the h^{th} plurality of parameters of Gaussian mixture model, namely the means μₖ^{h} and variances σₖ^{h}, k=1, 2, . . . , K, which correspond to the specific distribution of an arbitrary distribution noise to be generated, from the RAM for digital synthesis, where the k^{th} Gaussian noise signal is:

$${y}_{k n}^{h} = {σ}_{k}^{h} {x}_{n} + {μ}_{k}^{h}$$

where the multiplication operations and add operation are realized by Floating-point IP;
2.3). limiting amplitude
limiting the amplitude of the k^{th} Gaussian noise signal yₖₙ^{h}:

$${y}_{kn}^{h} = \{ \begin{matrix}{y}_{kn}^{h} , & {y}_{kn}^{h} ∈ [ {A}_{min} , {A}_{max} ] \\ {y}_{k ( n - 1 )}^{h} , & otherwise\end{matrix}$$

where yₖ₀^{h}=μₖ^{h};
2.4). normalizing
normalizing the k^{th} amplitude limited Gaussian noise signal yₖₙ^{h} to obtain the k^{th} Gaussian noise signal Dₖₙ^{h}:

$${D}_{k n}^{h} = ⌊ \frac{{y}_{k n}^{h} - {A}_{min}}{{A}_{max} - {A}_{min}} \cdot ( {2}^{{N}_{D A C}} - 1 ) ⌋ = ⌊ ( {y}_{k n}^{h} - offset ) \cdot gain ⌋$$

where parameters offset and gain are as follows:

$$offset = {A}_{min} , gain = \frac{{2}^{{N}_{DAC}} - 1}{{A}_{max} - {A}_{min}}$$

where parameters offset and gain are sent from the upper computer, and the data type of parameters offset and gain is double-precision floating point;
transforming the k^{th} Gaussian noise signal Dₖₙ^{h} into a fixed-point signal according to the bit-width N_{ADC} of the DAC;
2.5). outputting an analogy noise signal
successively inputting the K Gaussian noise signal Dₖₙ^{h}, k=1, 2, . . . , K to the DAC, which has one input and one output, to obtain an analogy signal, amplifying the obtained analogy signal Aₘₐₓ−Aₘᵢₙ times and setting bias voltage to Aₘᵢₙ to obtain an analogy noise signal with amplitude interval [Aₘᵢₙ, Aₘₐₓ], then outputting the analogy noise signal;
2.6). repeating step 2.2)˜step 2.5), when a next random number rₙ₊₁ is outputted, then an arbitrary distribution noise signal with specific distribution is outputted.

The objectives of the present invention are realized as follows:

In prior art, acceptance-rejection method has lower resource consumption, only a discretized probability distribution function ƒ(x) needs to store, however, the rate of generating random numbers is unstable. Look-up table method is simple and visual way, and no complex computation is needed, the output speed of random numbers is fast and stable, however, the output of random numbers depends on the prestored random numbers of given probability distribution function ƒ(x), randomness is weak, and the output error of lower probability numbers is large due to the limit of storage depth of ROM.

In accordance with the present invention, a method for real-time synthesizing an arbitrary distribution noise signal based on Gaussian mixture model is provided, which comprises two parts respectively processed by an upper computer and a FPGA. Wherein the upper computer firstly fits H given distribution function ƒ(x) to obtain H pluralities of K pairs of means μₖ^{h} and variances σₖ^{h}, h=1, 2, . . . , H, k=1, 2, . . . , K by using Expectation Maximization (EM) algorithm based on a weakened Gaussian Mixture Model (GMM), each pair of mean μₖ^{h} and variance σₖ^{h} corresponds an arbitrary Gaussian distribution synthesis model, then the upper computer sends H pluralities of K pairs of means μₖ^{h} and variances σₖ^{h}, h=1, 2, . . . , H, k=1, 2, . . . , K to the FPGA. The FPGA firstly stores the H pluralities of K pairs of means μₖ^{h} and variances σₖ^{h}, h=1, 2, . . . , H, k=1, 2, . . . , K into a RAM, function values that box-muller transformation needs into ROM 1 and ROM 2, then takes a chaos model as a digital entropy source to generate N₁+N₂ bits uniformly distributed random numbers. For the n^{th} number rₙ of N₁+N₂ bits uniformly distributed random numbers, it is divided into two parts, which are taken as two addresses to address ROM 1 and ROM 2 respectively and obtain two function values. The two function values are multiplied to obtain a random number xₙ, which obeys standard Gaussian distribution. Then the means μₖ^{h} and variances σₖ^{h}, k=1, 2, . . . , K, which correspond to the specific distribution of an arbitrary distribution noise to be generated, are read out from the RAM to synthesizing the k^{th} Gaussian noise signal yₖₙ^{h}, which is sent to a DAC for digital to analogy transformation after amplitude limitation and normalization, and the obtained analogy signal is amplified Aₘₐₓ−Aₘᵢₙ times and set the bias voltage to Aₘᵢₙ to obtain an analogy noise signal with amplitude interval [Aₘᵢₙ, Aₘₐₓ]. Repeating when a next random number rₙ₊₁ is outputted, then an arbitrary distribution noise signal with specific distribution is outputted.

In the present invention, the random numbers are transformed directly, and arbitrary distribution numbers with specific distribution can be generated randomly and stably, the randomness is unaffected. Meanwhile, when a specific distribution of an arbitrary distribution noise signal needs to be reassigned, we can just choose another plurality of parameters of Gaussian mixture model, namely the means μₖ^{h} and variances σₖ^{h}, k=1, 2, . . . , K, which correspond to the specific distribution of an arbitrary distribution noise to be generated from the RAM, the configuration is flexible and configuration parameters is much more less.

### BRIEF DESCRIPTION OF THE DRAWING

The above and other objectives, features and advantages of the present invention will be more apparent from the following detailed description taken in conjunction with the accompanying drawings, in which:

FIG. 1 is an illustration of acceptance-rejection method;

FIG. 2 is a process diagram of look-up table method;

FIG. 3(a)-FIG. 3(b) are illustrations of probability distribution functions before and after discretization, where FIG. 3(a) is a curve of probability distribution function before discretization, FIG. 3(b) is a curve of probability distribution function after discretization;

FIG. 4 is an illustration of a Gaussian mixture model;

FIG. 5 is a weakened illustration of a Gaussian mixture model;

FIG. 6 is a flow diagram of a method for real-time synthesizing an arbitrary distribution noise signal based on Gaussian mixture model in accordance with the present invention;

FIG. 7 is a schematic diagram of a method for real-time synthesizing an arbitrary distribution noise signal based on Gaussian mixture model in accordance with the present invention;

FIG. 8 is a phase trajectory diagram of uniformly distributed random numbers outputted by a modulus 6-dimensional chaos model;

FIG. 9 is a curve illustration of a distribution function ƒ(x) to be fitted;

FIG. 10 is an illustration of fitting by using Expectation Maximization algorithm based on a weakened Gaussian Mixture Model;

FIG. 11 is an illustration of an final outputted arbitrary distribution noise signal with specific distribution in accordance with one embodiment of the present invention.

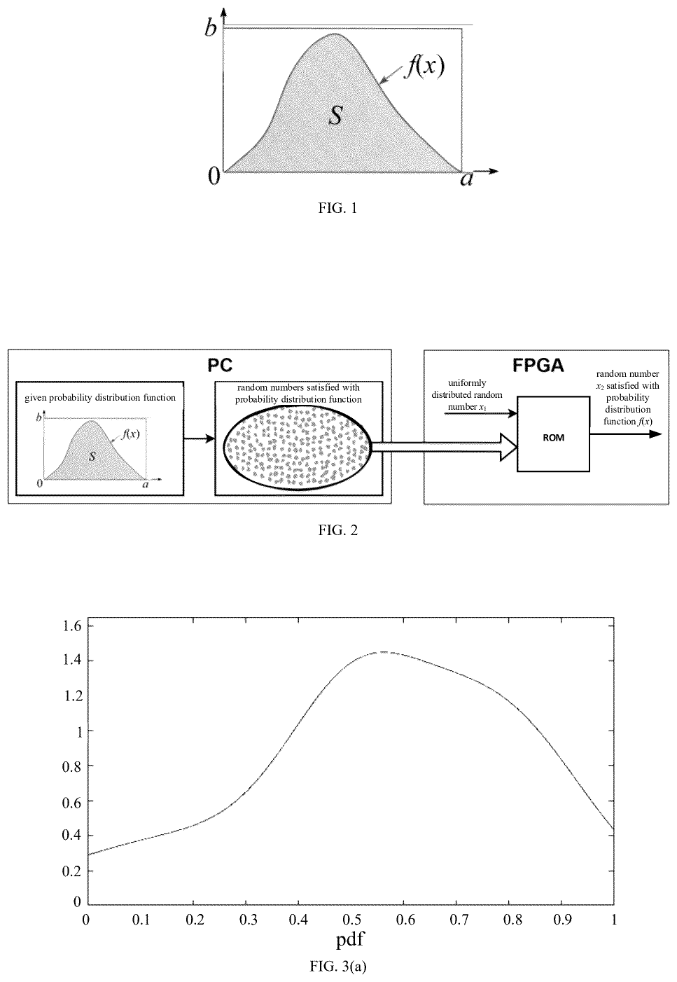

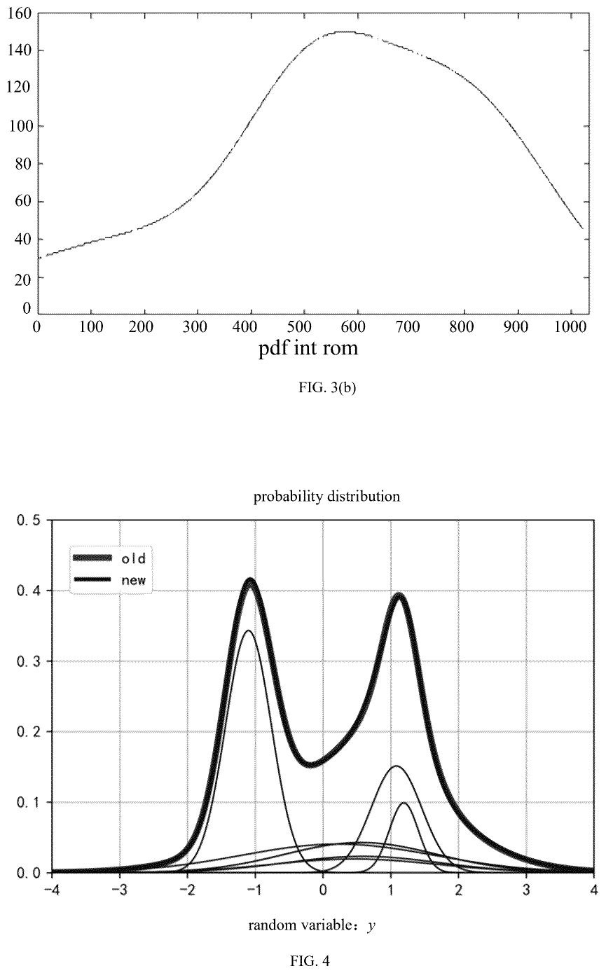

### DETAILED DESCRIPTION OF THE PREFERRED EMBODIMENT

Hereinafter, preferred embodiments of the present invention will be described with reference to the accompanying drawings. It should be noted that the similar modules are designated by similar reference numerals although they are illustrated in different drawings. Also, in the following description, a detailed description of known functions and configurations incorporated herein will be omitted when it may obscure the subject matter of the present invention.

In the present invention, firstly an upper computer fits H given distribution function ƒ(x) to obtain H pluralities of K pairs of means μₖ^{h} and variances σₖ^{h}, h=1, 2, . . . , H, k=1, 2, . . . , K by using Expectation Maximization (EM) algorithm based on a weakened Gaussian Mixture Model (GMM), each pair of mean μₖ^{h} and variance σₖ^{h} corresponds an arbitrary Gaussian distribution synthesis model, then a FPGA chooses the h^{th} plurality of parameters of Gaussian mixture model, namely the means μₖ^{h} and variances σₖ^{h}, k=1, 2, . . . , K, which correspond to the specific distribution of an arbitrary distribution noise to be generated, from the RAM for digital synthesis, and constructs a Gaussian mix model of corresponding fitting parameters to realize the generation of arbitrary given distribution numbers.

### 1. Basic Theory

### 1.1 Gaussian Mixture Model (GMM)

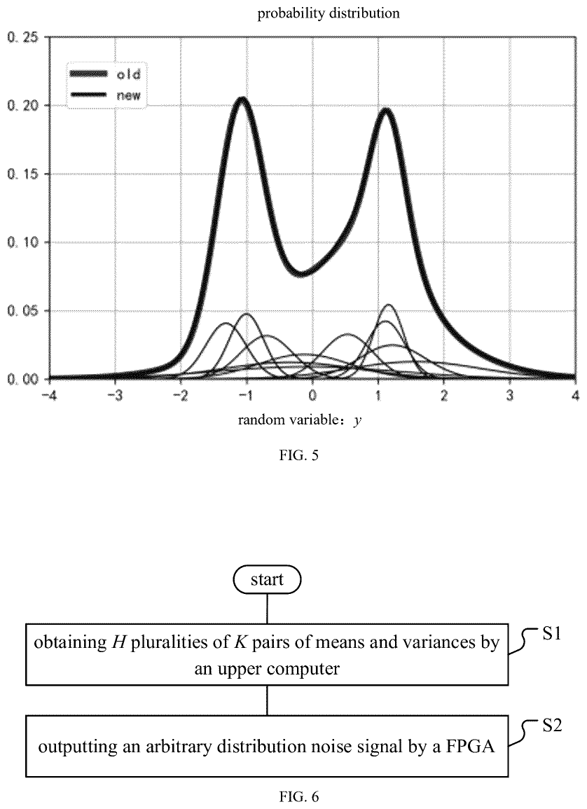

As shown in FIG. 4, Gaussian mixture model (curve old) can be seen as a model composed by K individual Gaussian models (curve new), the K individual Gaussian models are the hidden variables of Gaussian mixture model. Gaussian mixture model has the following probability distribution model:

P(y|θ)=Σₖ₌₁^{K}αₖϕ(γ|(θₖ))

where αₖ is proportion coefficient of the k^{th} individual Gaussian model, αₖ≥0, and:

Σₖ₌₁^{K}αₖ=1

ϕ(γ|(θₖ) is a Gaussian distribution density function, θₖ=(μₖ,σₖ²), μₖ, σₖ are respectively the mean and the variance of the k^{th} individual Gaussian model, Gaussian distribution density function ϕ(γ|(θₖ) is:

$$ϕ ( y \vert ( {θ}_{k} ) = \frac{1}{\sqrt{2 π} {σ}_{k}} exp ( - \frac{{( y - {μ}_{k} )}^{2}}{2 {σ}_{k}^{2}} )$$

ϕ(γ|(θₖ) also can be called as the k^{th} individual Gaussian model;

Gaussian mixture model is the extension of individual Gaussian distribution density function, and can smoothly approximate any arbitrary shape of distribution density. Based this property, the present invention constructs a parameter adjustable Gaussian mixture model to realize the generation of arbitrary given distribution numbers.

The proportion coefficient αₖ of Gaussian mixture model reflects the contribution ratio of an individual Gaussian distribution density function, however, it is complicated to realize the proportion coefficient αₖ in a FPGA: complicated logics are needed in the FPGA to realize the output of an individual Gaussian model according to its own proportion coefficient. For easy realization in FPGA, the present invention uses fixed proportion coefficients, namely αₖ=1/K, k=1, 2, . . . , K, in other words, sets the contribution ratios of all individual Gaussian models to the same, then Gaussian mixture model turns to as follows:

$$P ( y \vert θ ) = {\sum }_{k = 1}^{K} \frac{1}{K} ϕ ( y \vert ( {θ}_{k} ) )$$

Hereinafter, the above model is referred as weakened Gaussian mixture model, which is shown as FIG. 5.

Comparing to standard Gaussian mixture model, when a weakened Gaussian mixture model is used to fit any arbitrary shape of distribution density, it needs more individual Gaussian models (namely a larger K should be chosen) to realize the closest fitting effect due to lacking a plurality of adjustable parameters (all proportion coefficients αₖ, k=1, 2, . . . , K are fixed to 1/K). However, the design of weakened Gaussian mixture model evades proportion coefficients αₖ, k=1, 2, . . . , K and simply increases the numbers of individual Gaussian models, which can be realized in a FPGA.

### 1.2 Expectation Maximization Algorithm

After determining the basic idea of using a weakened Gaussian mixture model to realize the fitting of any arbitrary shape of distribution density, the further problem is how to determine the relevant parameters of the weakened Gaussian mixture model, namely how to determine the mean and variance of each individual Gaussian model, thus the use of expectation maximization algorithm is needed.

Expectation maximization algorithm is a kind of iterative algorithm, which is proposed by Dempster et al. and used for the maximum likelihood estimate (MLE) or maximum a posteriori (MAP) estimate of parameters of a probability model having hidden variables. Each iteration of expectation maximization algorithm has two steps: Expectation-step calculates an expectation, Maximization-step calculates a maximization, thus why the algorithm is called expectation maximization algorithm (abbreviated as EM algorithm).

The core idea of EM algorithm is very simple, dividing EM algorithm into two steps: Expectation-step and Maximization-step. Expectation-step firstly estimates parameters through current model and observation data, then calculates the expected value of likelihood function by using the estimated parameters. Maximization-step is finding out the corresponding parameters, when the likelihood function is at its maximum. For the algorithm can guarantee that the likelihood function after each iteration will increase, the likelihood function eventually will converge.

The details of EM algorithm are as follows:
Inputs: observation variable data Y, hidden variable data Z, joint probability distribution P(Y,Z|θ) and conditional probability distribution P(Y|Z,θ);
Output: model parameter θ.
(1). Choose the initial value θ⁽⁰⁾ of model parameter θ and start to iterate;
(2). Expectation-step: the estimated value of model parameter θ of the i^{th} iteration is denoted by θ⁽ⁱ⁾, at the i+1^{th} iteration, calculates:

Q(θ,θ⁽ⁱ⁾)=Ez[log P(Y,Z|θ)|Y,θ⁽ⁱ⁾]=Σ_{Z} log P(Y,Z|θ)P(Z|Y,θ⁽ⁱ⁾)
where P(Z|Y, θ⁽ⁱ⁾) is the conditional probability distribution of hidden variable data under given observation variable data Y and current model parameter θ⁽ⁱ⁾;
(3). Maximization-step: calculates model parameter θ maximizing Q(θ, θ⁽ⁱ⁾) and determines the estimated value of model parameter θ⁽ⁱ⁺¹⁾ of the i^{th} iteration:

$${θ}^{( i + 1 )} = arg {max}_{θ} Q ( θ , {θ}^{( i )} )$$

(4). Repeats expectation-step and maximization-step, until the convergence is realized.
1.3 Parameter Estimation of Weaken Gaussian Mixture Model by Using EM Algorithm

The weaken Gaussian mixture model used in the present invention can be expressed as follows:

$$P ( y \vert θ ) = \frac{1}{K} {\sum }_{k = 1}^{K} ϕ ( y \vert ( {θ}_{k} ) )$$

where ϕ(y|(θₖ) is a Gaussian distribution density function, which is also called the k^{th} individual Gaussian model, θₖ=(μₖ,σₖ²), and the k^{th} individual Gaussian model can be expressed as follows:

$$ϕ ( y \vert ( {θ}_{k} ) = \frac{1}{\sqrt{2 π} {σ}_{k}} exp ( - \frac{{( y - {μ}_{k} )}^{2}}{2 {σ}_{k}^{2}} )$$

Specific to parameter estimation of the weaken Gaussian mixture model used in the present invention, the detailed steps of EM algorithm are as follows:

### (1). Determining a Hidden Variable

Observation data is denoted by yⱼ, j=1, 2, . . . , N, and the data reflecting observation data yⱼ comes from the k^{th} individual Gaussian model, k=1, 2, . . . K, is unknown, and can be denoted by hidden variable yⱼₖ, its definition is as follows:

$${γ}_{jk} = \{ \begin{matrix}\begin{matrix}1 , the {j}^{th} observation data {y}_{j} comes from \\ the kth individual Gaussian model\end{matrix} \\ 0 , otherwise\end{matrix}$$

$$j = 1 , 2 , … , N ; k = 1 , 2 , … , K$$

Hidden variable γⱼₖ is a random variable of 0-1.

Having observation data yⱼ and hidden variable yⱼₖ, then the complete data are as follows:

(yⱼ,γⱼ₁,γⱼ₂, . . . ,γ_{jK}),j=1,2, . . . ,N

Thus the logarithm likelihood function of the complete data can be written as follows:

$$log P ( y , γ \vert θ ) = {\sum }_{k = 1}^{K} {n}_{k} log \frac{1}{K} + {\sum }_{k = 1}^{K} {\sum }_{j = 1}^{N} {γ}_{j k} [ log ( \frac{1}{\sqrt{2 π}} ) - log {σ}_{k} - \frac{1}{2 {σ}_{k}^{2}} {( {y}_{j} - {μ}_{k} )}^{2} ]$$

### (2). The Expectation-Step of EM Algorithm: Determining Q Function

$$\begin{matrix}Q ( θ , {θ}^{( i )} ) = E [ log P ( y , γ \vert θ ) \vert y , {θ}^{( i )} ] \\ = E \{ {\sum }_{k = 1}^{K} {n}_{k} log \frac{1}{K} + {\sum }_{k = 1}^{K} {\sum }_{j = 1}^{N} {γ}_{j k} [ log ( \frac{1}{\sqrt{2 π}} ) - log {σ}_{k} - \frac{1}{2 {σ}_{k}^{2}} {( {y}_{j} - {μ}_{k} )}^{2} ] \} \\ = {\sum }_{k = 1}^{K} \{ {n}_{k} log \frac{1}{K} + {\sum }_{j = 1}^{N} ( E {γ}_{j k} ) [ log ( \frac{1}{\sqrt{2 π}} ) - log {σ}_{k} - \frac{1}{2 {σ}_{k}^{2}} {( {y}_{j} - {μ}_{k} )}^{2} ] \}\end{matrix}$$

Here, we need to calculate E(γⱼₖ|y, θ), which is denoted by ŷⱼₖ:

$$\begin{matrix}{\hat{γ}}_{j k} = E ( {γ}_{j k} \vert y , θ ) = P ( {γ}_{j k} = 1 \vert y , θ ) \\ = \frac{{}^{P} ( {γ}_{j k} = 1 , {y}_{j} \vert θ )}{{\sum }_{k = 1}^{K} {}^{P} ( {γ}_{j k} = 1 , {y}_{j} \vert θ )} \\ = \frac{ϕ ( {y}_{j} \vert ( {θ}_{k} ) )}{K {\sum }_{k = 1}^{K} ϕ ( {y}_{j} \vert ( {θ}_{k} ) )} , j = 1 , 2 , … , N ; k = 1 , 2 , … , K\end{matrix}$$

ŷⱼₖ is the probability that observation data yⱼ comes from the k^{th} individual Gaussian model under the current model parameter, also called as the responsivity of the k^{th} individual Gaussian model to observation data yⱼ. The above expression in iteration can be rewritten as follows:

$${γ}_{j k}^{( i )} = \frac{ϕ ( {y}_{j} \vert ( {μ}_{k}^{( i )} , {σ}_{k}^{( i )} ) )}{K {\sum }_{k = 1}^{K} ϕ ( {y}_{j} \vert ( {μ}_{k}^{( i )} , {σ}_{k}^{( i )} ) )}$$

where ϕ(yⱼ|(μₖ⁽ⁱ⁾,σₖ⁽ⁱ⁾)) is a Gaussian distribution density function constructed by the k^{th} pair of mean μₖ⁽ⁱ⁾ and variance σₖ⁽ⁱ⁾ at the i^{th} iteration, ϕ(γⱼ|(μₖ⁽ⁱ⁾,σₖ⁽ⁱ⁾)) is a Gaussian distribution density of a Gaussian distribution density function ϕ(y|(μₖ⁽ⁱ⁾,σₖ⁽ⁱ⁾)) at y=yⱼ, probability γⱼₖ⁽ⁱ⁾ is the responsivity of the k^{th} individual Gaussian model (the k^{th} arbitrary Gaussian distribution synthesis model in the present invention) to observation data yⱼ.
substituting ŷⱼₖ=Eγⱼₖ and nₖ=Σ₁₌₁^{N}Eγⱼₖ into the determined Q function, then we can obtain:

$$Q ( θ , {θ}^{( i )} ) = {\sum }_{k = 1}^{K} {n}_{k} log \frac{1}{K} + {\sum }_{j = 1}^{N} {\hat{γ}}_{j k} [ log ( \frac{1}{\sqrt{2 π}} ) - log {σ}_{k} - \frac{1}{2 {σ}_{k}^{2}} {( {y}_{j} - {μ}_{k} )}^{2} ]$$

### (3). The Maximization-Step of EM Algorithm

The maximization-step of i^{th} iteration is calculating model parameter θ which maximizes Q(θ,θ⁽ⁱ⁾), namely calculating the model parameters of next round iteration:

$${θ}^{( i + 1 )} = arg {max}_{θ} Q ( θ , {θ}^{( i )} )$$

Denoting model parameter θ⁽ⁱ⁺¹⁾ by μₖ, σₖ², we can calculate μₖ, σₖ² by calculating the partial derivatives of Q function by using μₖ, σₖ² respectively, and obtain:

$$\begin{matrix}{\hat{μ}}_{k} = \frac{{\sum }_{j = 1}^{N} {\hat{γ}}_{j k} {y}_{j}}{{\sum }_{j = 1}^{N} {γ}_{j k}^{( i )}} , k = 1 , 2 , … , K \\ {\hat{σ}}_{k}^{2} = \frac{{\sum }_{j = 1}^{N} {{\hat{γ}}_{j k} ( {y}_{j} - {\hat{μ}}_{k} )}^{2}}{{\sum }_{j = 1}^{N} {\hat{γ}}_{j k}} , k = 1 , 2 , … , K\end{matrix}$$

Repeating the above calculation, until the value of logarithm likelihood function has no significant variation.

Rewriting the above expression in iteration, then we can obtain the mean μₖ⁽ⁱ⁺¹⁾ and variance σₖ⁽ⁱ⁺¹⁾ at the i^{th} iteration:

$$\begin{matrix}{μ}_{k}^{( i + 1 )} = \frac{{\sum }_{j = 1}^{N} {γ}_{j k}^{( i )} {y}_{j}}{{\sum }_{j = 1}^{N} {γ}_{j k}^{( i )}} \\ {( {σ}_{k}^{( i + 1 )} )}^{2} = \frac{{\sum }_{j = 1}^{N} {{γ}_{j k}^{( i )} ( {y}_{j} - {μ}_{k}^{( i )} )}^{2}}{{\sum }_{j = 1}^{N} {γ}_{j k}^{( i )}}\end{matrix}$$

### 2. Implementation

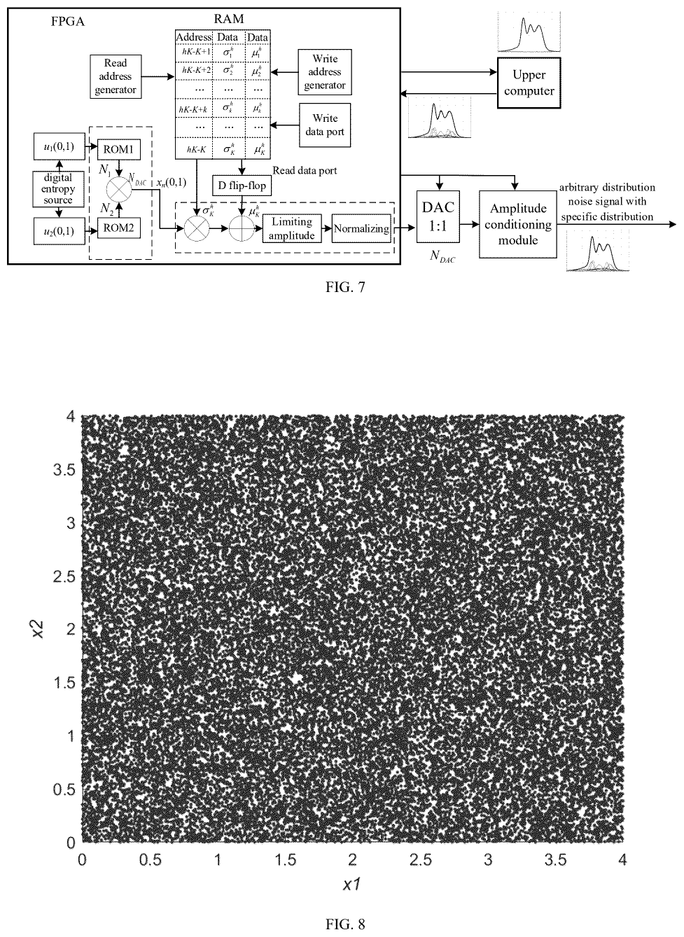

Based on the above basic theory, the present invention provides a method for real-time synthesizing an arbitrary distribution noise signal based on Gaussian mixture model. In one embodiment, as shown in FIG. 6 and FIG. 7, it comprises the following steps:
Step S1: obtaining H pluralities of K pairs of means and variances by an upper computer
Step S1.1: taking a distribution function of arbitrary distribution numbers as a distribution function ƒ(x) to be fitted, and obtaining N observation data yⱼ=ƒ(xⱼ), j=1, 2, . . . , N, where xⱼ is a number uniformly taken from a value range of the distribution function ƒ(x).
Step S1.2: initializing K pairs of means μₖ⁽⁰⁾ and variances σₖ⁽⁰⁾, k=1, 2, . . . , K, initializing iteration number i=1, and letting amplitude interval of a noise signal to be fitted is [Aₘᵢₙ, Aₘₐₓ], then K pairs of initial values of K arbitrary Gaussian distribution synthesis models are set as follows:

$$\{ \begin{matrix}a = \frac{{A}_{max} - {A}_{min}}{K} \\ {u}_{k}^{( 0 )} = {A}_{min} + ( k - 0.5 ) a \\ {σ}_{k}^{( 0 )} = 1 \\ \end{matrix} \qquad ( 1 )$$

In the embodiment, K=16.
Step S1.3: calculating a probability γⱼₖ⁽ⁱ⁾ that the j^{th} observation data yⱼ at the i^{th} iteration is from the k^{th} arbitrary Gaussian distribution synthesis model:

$${γ}_{j k}^{( i )} = \frac{ϕ ( {y}_{j} \vert ( {μ}_{k}^{( i )} , {σ}_{k}^{( i )} ) )}{K {\sum }_{k = 1}^{K} ϕ ( {y}_{j} \vert ( {μ}_{k}^{( i )} , {σ}_{k}^{( i )} ) )} \qquad ( 2 )$$

where ϕ(y|(μₖ⁽ⁱ⁾,σₖ⁽ⁱ⁾)) is a Gaussian distribution density function constructed by the k^{th} pair of mean μₖ⁽ⁱ⁾ and variance σₖ⁽ⁱ⁾ at the i^{th} iteration, ϕ(yⱼ|(μₖ⁽ⁱ⁾,σₖ⁽ⁱ⁾)) is a Gaussian distribution density of a Gaussian distribution density function ϕ(y|(μₖ⁽ⁱ⁾,σₖ⁽ⁱ⁾)) at y=yⱼ.
Step S1.4: calculating mean μₖ⁽ⁱ⁺¹⁾ and variance σₖ⁽ⁱ⁺¹⁾ at the i+1^{th} iteration:

$${μ}_{k}^{( i + 1 )} = \frac{{\sum }_{j = 1}^{N} {γ}_{j k}^{( i )} {y}_{j}}{{\sum }_{j = 1}^{N} {γ}_{j k}^{( i )}} \qquad ( 3 )$$

$$( {σ}_{k}^{( i + 1 )} ) = \frac{{\sum }_{j = 1}^{N} {{γ}_{j k}^{( i )} ( {y}_{j} - {μ}_{k}^{( i )} )}^{2}}{{\sum }_{j = 1}^{N} {γ}_{j k}^{( i )}} \qquad ( 4 )$$

Step S1.5: judging whether μₖ⁽ⁱ⁺¹⁾−μk₍ᵢ₎ is less than a set threshold ε₁ and whether σₖ⁽ⁱ⁺¹⁾−σₖ⁽ⁱ⁾ is less than a set threshold ε₂, if yes, or iteration number i reaches a set upper limit, terminating iteration and taking mean μₖ⁽ⁱ⁺¹⁾ and variance σₖ⁽ⁱ⁺¹⁾ respectively as the mean μₖ and variance σₖ of the k^{th} arbitrary Gaussian distribution synthesis model, k=1, 2, . . . , K, otherwise, letting i=i+1 and returning to step S1.3.
Step S1.6: replacing distribution function of arbitrary distribution numbers and repeating steps S1.1˜S1.5 to obtain H pluralities of K pairs of means and variances, where the k^{th} pair of means and variances in the h^{th} plurality are denoted by means μₖ^{h} and variances σₖ^{h}, h=1, 2, . . . , H, k=1, 2, . . . , K, then sending the H pluralities of K pairs of means and variances to a FPGA.
Step S2: outputting an arbitrary distribution noise signal by a FPGA

The standard high speed noise synthesis obeys Box-Muller formula, its expression is:

$$\{ \begin{matrix}\sqrt{- 2 ln ( {u}_{2} )} sin ( 2 π {u}_{1} ) \\ \sqrt{- 2 ln ( {u}_{2} )} cos ( 2 π {u}_{1} )\end{matrix} \qquad ( 5 )$$

where u₁, u₂ are two independent random numbers uniformly distributed in (0,1). In the present invention, the calculations of sin(2πu₁) and \sqrt{−2 ln(u₂)} are performed by using a look-up table: the values are pre-stored in ROM 1 and ROM 2 respectively, when calculating, a pair of uniformly distributed random numbers are taken respectively as the read addresses of ROM 1 and ROM 2 to read out the corresponding values of sin(2πu₁) and \sqrt{−2 ln(u₂)}, then the values are multiplied to obtain a random number x, which obeys standard Gaussian distribution. The details of this step are as follows:
Step S2.1: in the FPGA, storing the function values that box-muller transformation needs by ROM 1 and ROM 2: ROM 1 is used to store the corresponding function values of cos(2πu₁) or sin(2πu₁), its address bit-width is N₁, its data bit-width is 64, its data type is double-precision floating point, and u₁ is:

$${u}_{1} = \frac{{b}_{1}}{{2}^{{N}_{1}} - {b}_{1}} , {b}_{1} = 0 , 1 , … , {2}^{{N}_{1}} - 1 \qquad ( 6 )$$

where b₁ is an address;
ROM 2 is used to store the corresponding function values of \sqrt{−2 ln(u₂)}, its address bit-width is N₂, its data bit-width is 64, its data type is double-precision floating point, and u₂ is:

$$\begin{matrix}{u}_{2} = 2 π \frac{{b}_{2}}{{2}^{{N}_{2}}} , & {b}_{2} = 1 , 2 , … {2}^{{N}_{2}}\end{matrix} \qquad ( 7 )$$

where b₂ is an address;
storing the H pluralities of K pairs of means μₖ^{h} and variances σₖ^{h}, h=1, 2, . . . , H, k=1, 2, . . . , K, obtained by the upper computer in a RAM: simultaneously caching H pluralities of parameters of different Gaussian mixture models, each plurality of parameters corresponds a Gaussian mixture model, which comprise means μₖ and variances σₖ, k=1, 2, . . . , K of K arbitrary Gaussian distribution synthesis models and are used to generate a different arbitrary distribution noise signal, where the storage depth of the RAM is H×K, the data bit-width is 128, each data consists of a mean μₖ^{h} and a variance σₖ^{h} with 64 bits respectively.
Step S2.2: synthesizing the k^{th} Gaussian noise signal
firstly, generating N₁+N₂ bits uniformly distributed random numbers by taking a chaos model as a digital entropy source, where the n^{th} number is denoted by rₙ, n is a serial number, addressing ROM 1 by taking the high N₁ bits as address b₁ to obtain corresponding function value of cos(2πu₁) or sin(2πu₁), addressing ROM 2 by taking the low N₂ bits as address b₂ to obtain corresponding function value of \sqrt{−2 ln(u₂)}, where address bit-width N₁ of ROM 1 and address bit-width N₂ of ROM 2 satisfy the following constraints:

$$\{ \begin{matrix}{N}_{1} \geq ⌈ \frac{{N}_{DAC}}{2} ⌉ \\ {N}_{2} \geq ⌈ \frac{{N}_{DAC}}{2} ⌉\end{matrix} \qquad ( 8 )$$

where N_{DAC} is the bit-width of a DAC, when ROM 1 and ROM 2 have enough storage resource, For less fitting error, the value of address bit-width N₁, N₂ should be as large as possible;
multiplying the function value of cos(2πu₁) or sin(2πu₁) by the function value of \sqrt{−2 ln(u₂)} to obtain a random number, which obeys standard Gaussian distribution and is denoted by xₙ; in present invention, xₙ has N_{DAC} bits;
then reading out the h^{th} plurality of parameters of Gaussian mixture model, namely the means μₖ^{h} and variances σₖ^{h}, k=1, 2, . . . , K, which correspond to the specific distribution of an arbitrary distribution noise to be generated, from the RAM for digital synthesis, where the k^{th} Gaussian noise signal is:

$${y}_{k n}^{h} = {σ}_{k}^{h} {x}_{n} + {μ}_{k}^{h}$$

where the multiplication operations and add operation are realized by Floating-point IP.

In the embodiment, the read address of the RAM is generated by the logic of the FPGA. When the given or specific distribution needs to be generated and the corresponding h^{th} plurality of parameters of Gaussian mixture model in RAM needs to be read out, the read address of the RAM increases periodically within the range of hK−K+1 to hK, continuously reading out the corresponding h^{th} plurality of parameters of Gaussian mixture model, namely the means μₖ^{h} and variances σₖ^{h}, k=1, 2, . . . , K.
Step S2.3: limiting amplitude

The Gaussian noise signals outputted by K Gaussian mixture models form a digital arbitrary distribution noise which has a specific or given distribution. However, if the digital arbitrary distribution noise directly connects to a DAC for analogy output, the amplitude may cross the bound of the DAC, the DAC will cut the digital arbitrary distribution noise, which will lead to output error of the DAC. Thus, an amplitude limitation is needed for the Gaussian noise signal.

The upper computer respectively transforms the upper boundary Aₘₐₓ and the lower boundary Aₘᵢₙ into double-precision floating points and sends to the FPGA, using the Compare function of two Floating-point IP cores in the FPGA to limiting the amplitude of the k^{th} Gaussian noise signal yₖₙ^{h}. When the outputs of two Floating-point IP cores are “1”, the k^{th} Gaussian noise signal yₖₙ^{h} remains unchanged, otherwise, the k^{th} Gaussian noise signal yₖₙ^{h} equals to yₖ₍ₙ₋₁₎^{H}. It should be noted that Compare operation needs one clock, so we need to delay the k^{th} Gaussian noise signal yₖₙ^{h} that is currently being compared one clock, the next k^{th} Gaussian noise signal yₖₙ^{h} can be correctly received. The details are as follows:
limiting the amplitude of the k^{th} Gaussian noise signal yₖₙ^{h}:

$${y}_{kn}^{h} = \{ \begin{matrix}{y}_{kn}^{h} , & {y}_{kn}^{h} ∈ [ {A}_{min} , {A}_{max} ] \\ {y}_{k ( n - 1 )}^{h} , & otherwise\end{matrix}$$

where yₖ₀^{h}=μₖ^{h}.
Step S2.4: normalizing
normalizing the k^{th} amplitude limited Gaussian noise signal yₖₙ^{h} to obtain the k^{th} Gaussian noise signal Dₖₙ^{h}:

$${D}_{k n}^{h} = ⌊ \frac{{y}_{k n}^{h} - {A}_{min}}{{A}_{max} - {A}_{min}} \cdot ( {2}^{{N}_{D A C}} - 1 ) ⌋ = ⌊ ( {y}_{k n}^{h} - offset ) \cdot gain ⌋$$

where parameters offset and gain are as follows:

$$offset = {A}_{min} , gain = \frac{{2}^{{N}_{DAC}} - 1}{{A}_{max} - {A}_{min}}$$

where parameters offset and gain are sent from the upper computer, and the data type of parameters offset and gain is double-precision floating point;
transforming the k^{th} Gaussian noise signal Dₖₙ^{h} into a fixed-point signal according to the bit-width N_{ADC} of the DAC. In the embodiment, the transformation is realized by using the Float-to-fixed function of a Floating-point IP core in the FPGA.
Step S2.5: outputting an analogy noise signal
successively inputting the K Gaussian noise signal Dₖₙ^{h}, k=1, 2, . . . , K to the DAC, which has one input and one output, to obtain an analogy signal, amplifying the obtained analogy signal Aₘₐₓ−Aₘᵢₙ times and setting bias voltage to Aₘᵢₙ to obtain an analogy noise signal with amplitude interval [Aₘᵢₙ, Aₘₐₓ], then outputting the analogy noise signal.
Step S2.6: repeating Step S2.2˜Step S2.5, when a next random number rₙ₊₁ is outputted, then an arbitrary distribution noise signal with specific distribution is outputted.

In the embodiment, the chaos model is a modulus 6-dimensional chaos model, which is:

$${x}_{1 , n + 1} = mod ( {ax}_{1 , n} + {x}_{1 , n} {x}_{2 , n} + 2 {x}_{3 , n} + 7 {x}_{4 , n} + ( b - a ) {x}_{5 , n} - {x}_{2 , n} {x}_{5 , n} + {x}_{6 , n}^{2} , 4 )$$

$${x}_{2 , n + 1} = mod ( {x}_{1 , n} {x}_{2 , n} + f {x}_{2 , n} + 3 {x}_{3 , n} - 3 {x}_{4 , n} - {x}_{2 , n} {x}_{5 , n} , 4 )$$

$${x}_{3 , n + 1} = mod ( {x}_{1 , n} + {x}_{1 , n} {x}_{6 , n} + 5 {x}_{2 , n} + c {x}_{3 , n} + {x}_{3 , n} {x}_{6 , n} + ( d - c - {x}_{6 , n} ) {x}_{4 , n} - {x}_{5 , n} - {x}_{5 , n} {x}_{6 , n} , 4 )$$

$${x}_{4 n + 1} = mod ( {x}_{1 , n} {x}_{6 , n} + 5 {x}_{3 , n} + {x}_{3 , n} {x}_{6 , n} + d {x}_{4 , n} - {x}_{4 n} {x}_{6 , n} + {x}_{5 , n} {x}_{6 , n} , 4 )$$

$${x}_{5 , n + 1} = mod ( {x}_{1 , n} {x}_{2 , n} + 2 {x}_{3 , n} + 5 {x}_{4 , n} + b {x}_{5 , n} - {x}_{2 , n} {x}_{5 , n} + {x}_{6 , n}^{2} , 4 )$$

$${x}_{6 , n + 1} = mod ( {x}_{1 , n} + 2 {x}_{1 , n} {x}_{2 , n} - {x}_{2 , n} {x}_{4 , n} - {x}_{5 , n} + g ( {x}_{6 , n}^{3} + {x}_{6 , n}^{2} + {x}_{6 , n} ) , 4 )$$

where n is the serial number of iterations, namely the serial number of the N₁+N₂ bits uniformly distributed random numbers. The modulus 6-dimensional chaos model has chaotic property in large scope. Meanwhile, due to the join of modulus operation, the output of the modulus 6-dimensional chaos model has uniformly distribution property. Stimulating the modulus 6-dimensional chaos model by Matlab software, a phase trajectory diagram of dimensions x₁, x₂ is shown in FIG. 8. Obviously, we can see that the dimension x₁, x₂ have excellent uniformly distribution property. We can take the outputs of any one dimension as the N₁+N₂ bits uniformly distributed random numbers.

### Example

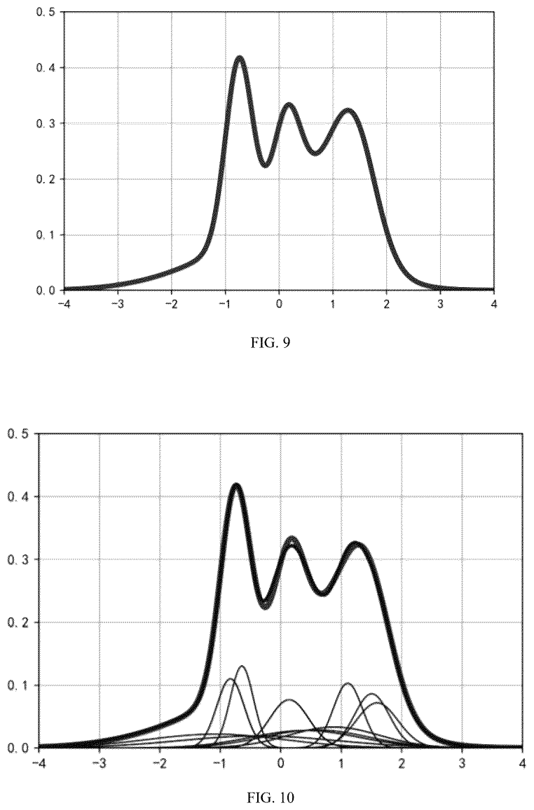

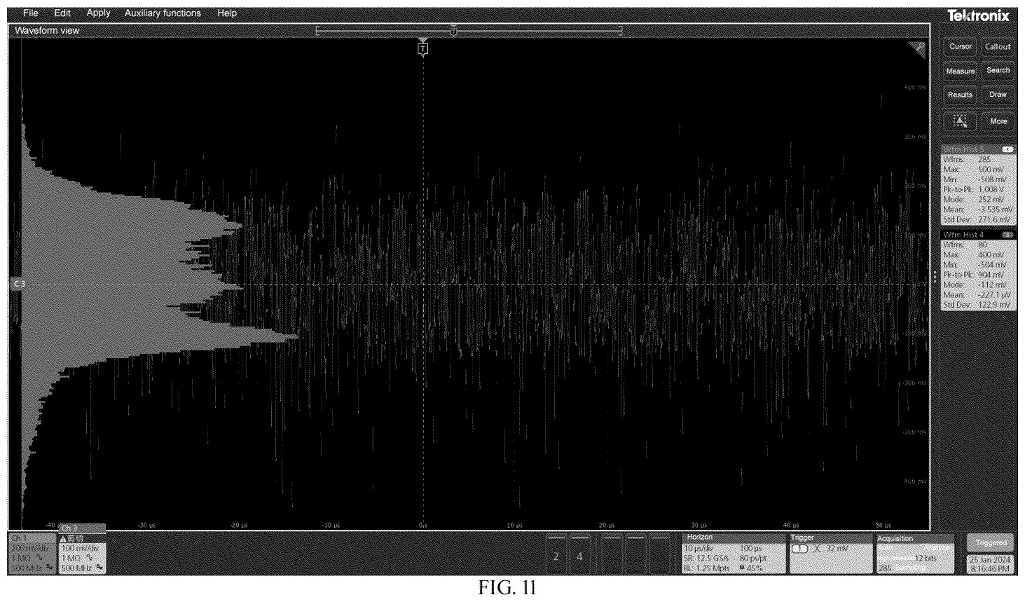

FIG. 9 shows a curve of a distribution function ƒ(x) to be fitted and FIG. 10 shows the fitting of the distribution function ƒ(x) by using Expectation Maximization algorithm based on a weakened Gaussian Mixture Model, K=16. From FIGS. 9 and 10, we can see that the weakened Gaussian Mixture Model perfectly realized the fitting of specific or give arbitrary distribution function ƒ(x). In the example, the 16 pairs of means and variances are as follows:

TABLE 1

| Mean μₖ | Variance σₖ | Mean μₖ | Variance σₖ |
|---|---|---|---|
| 1.602292355199216 | 0.2818544384589659 | −1.179381521186682 | 1.0944751157468844 |
| 0.7193172727124468 | 0.855456214281953 | 1.560146451621095 | 0.4353747667598236 |
| 0.7193172727124468 | 0.855456214281953 | −0.7310005154828475 | 0.1838244913268576 |
| −0.8128219691425068 | 0.2674165680243411 | −0.2865962397750367 | 1.3249891656221915 |
| 0.4096188880970521 | 0.7076207775729666 | −0.2865962397750367 | 1.3249891656221915 |
| 0.1675486288267253 | 0.41636030385951023 | −0.8128219691425068 | 0.2674165680243411 |
| 0.5629593049916832 | 0.7996097439159522 | 0.4096188880970521 | 0.7076207775729666 |
| 1.2471216914612082 | 0.22064799035171148 | 0.1675486288267253 | 0.41636030385951023 |

It should be noted that Expectation Maximization algorithm is sensitive to the initial value. To guarantee the fitting effect under finite precision in a FPGA. In the example, in the process of executing Expectation Maximization algorithm to fit a distribution function ƒ(x), we uniformly spread out the 16 pairs of means and variances according to the range of number axis, which avoids the means of the 16 pairs of Gaussian distributions being too centralized, and then, under the calculation of the finite precision in FPGA, the better fitting effect can be achieved.

After limiting the amplitudes of K Gaussian noise signals, normalizing and amplifying, we can obtain specific or given arbitrary distribution noise, which is drawn into a statistic chart, the result is shown in FIG. 11.

From FIG. 11, we can see that the obtained arbitrary distribution noise obeys specific or given arbitrary distribution, the result of the example demonstrates the effectiveness of the present invention.

While illustrative embodiments of the invention have been described above, it is, of course, understand that various modifications will be apparent to those of ordinary skill in the art. Such modifications are within the spirit and scope of the invention, which is limited and defined only by the appended claims.

What is claimed is:

1. A method for real-time synthesizing an arbitrary distribution noise signal based on Gaussian mixture, comprising:
(1). obtaining H pluralities of K pairs of means and variances by an upper computer
1.1). taking a distribution function of arbitrary distribution numbers as a distribution function ƒ(x) to be fitted, and obtaining N observation data yⱼ=ƒ(xⱼ), j=1, 2, . . . , N, where xⱼ is a number uniformly taken from a value range of the distribution function ƒ(x);
1.2). initializing K pairs of means μₖ⁽⁰⁾ and variances σₖ⁽⁰⁾, k=1, 2, . . . , K, initializing iteration number i=1, and letting amplitude interval of a noise signal to be fitted is [Aₘᵢₙ, Aₘₐₓ], then K pairs of initial values of K arbitrary Gaussian distribution synthesis models are set as follows:
$$\{ \begin{matrix}a = \frac{{A}_{max} - {A}_{min}}{K} \\ {u}_{k}^{( 0 )} = {A}_{min} + ( k - 0.5 ) a \\ {σ}_{k}^{( 0 )} = 1\end{matrix}$$
1.3). calculating a probability γⱼₖ⁽ⁱ⁾ that the j^{th} observation data yⱼ at the i^{th} iteration is from the k^{th} arbitrary Gaussian distribution synthesis model:
$${γ}_{j k}^{( i )} = \frac{ϕ ( {y}_{j} \vert ( {μ}_{k}^{( i )} , {σ}_{k}^{( i )} ) )}{K {Σ}_{k = 1}^{K} ϕ ( {y}_{j} \vert ( {μ}_{k}^{( i )} , {σ}_{k}^{( i )} ) )}$$
where ϕ(y|(μₖ⁽ⁱ⁾,σₖ⁽ⁱ⁾)) is a Gaussian distribution density function constructed by the k^{th} pair of mean μₖ⁽ⁱ⁾ and variance σₖ⁽ⁱ⁾ at the i^{th} iteration, ϕ(yⱼ|(μₖ⁽ⁱ⁾,σₖ⁽ⁱ⁾)) is a Gaussian distribution density of a Gaussian distribution density function ϕ(y|(μₖ⁽ⁱ⁾,σₖ⁽ⁱ⁾)) at y=yⱼ;
1.4). calculating mean μₖ⁽ⁱ⁺¹⁾ and variance σₖ⁽ⁱ⁺¹⁾ at the i+1^{th} iteration:
$${μ}_{k}^{( i + 1 )} = \frac{{Σ}_{j = 1}^{N} {γ}_{jk}^{( i )} {y}_{j}}{{Σ}_{j = 1}^{N} {γ}_{jk}^{( i )}}$$
$${( {σ}_{k}^{( i + 1 )} )}^{2} = \frac{{Σ}_{j = 1}^{N} {{γ}_{j k}^{( i )} ( {y}_{j} - {μ}_{k}^{( i )} )}^{2}}{{Σ}_{j = 1}^{N} {γ}_{j k}^{( i )}}$$
1.5). judging whether μₖ⁽ⁱ⁺¹⁾−μₖ⁽ⁱ⁾ is less than a set threshold ε₁ and whether σₖ⁽ⁱ⁺¹⁾−σₖ⁽ⁱ⁾ is less than a set threshold ε₂, if yes, or iteration number i reaches a set upper limit, terminating iteration and taking mean μₖ⁽ⁱ⁺¹⁾ and variance σₖ⁽ⁱ⁺¹⁾ respectively as the mean μₖ and variance σₖ of the k^{th} arbitrary Gaussian distribution synthesis model, k=1, 2, . . . , K, otherwise, letting i=i+1 and returning to step 1.3);
1.6). replacing distribution function of arbitrary distribution numbers and repeating steps 1.1)˜1.5) to obtain H pluralities of K pairs of means and variances, where the k^{th} pair of means and variances in the h^{th} plurality are denoted by means μₖ^{h} and variances σₖ^{h}, h=1, 2, . . . , H, k=1, 2, . . . , K, then sending the H pluralities of K pairs of means and variances to a FPGA;
(2). outputting an arbitrary distribution noise signal by a FPGA
2.1). in the FPGA, storing the function values that box-muller transformation needs by ROM 1 and ROM 2: ROM 1 is used to store the corresponding function values of cos(2πu₁) or sin(2πu₁), its address bit-width is N₁, its data bit-width is 64, its data type is double-precision floating point, and u₁ is:
$${u}_{1} = \frac{{b}_{1}}{{2}^{N} - {b}_{1}} , {b}_{1} = 0 , 1 , … , {2}^{{N}_{1}} - 1$$
where b₁ is an address;
ROM 2 is used to store the corresponding function values of \sqrt{−2 ln(u₂)}, its address bit-width is N₂, its data bit-width is 64, its data type is double-precision floating point, and u₂ is:
$${u}_{2} = 2 π \frac{{b}_{2}}{{2}^{{N}_{2}}} , {b}_{2} = 1 , 2 , … {2}^{{N}_{2}}$$
where b₂ is an address;
storing the H pluralities of K pairs of means μₖ^{h} and variances σₖ^{h}, h=1, 2, . . . , H, k=1, 2, . . . , K, obtained by the upper computer in a RAM: simultaneously caching H pluralities of parameters of different Gaussian mixture models, each plurality of parameters corresponds a Gaussian mixture model, which comprise means μₖ and variances σₖ, k=1, 2, . . . , K of K arbitrary Gaussian distribution synthesis models and are used to generate a different arbitrary distribution noise signal, where the storage depth of the RAM is H×K, the data bit-width is 128, each data consists of a mean μₖ^{h} and a variance σₖ^{h} with 64 bits respectively;
2.2). synthesizing the k^{th} Gaussian noise signal
firstly, generating N₁+N₂ bits uniformly distributed random numbers by taking a chaos model as a digital entropy source, where the n^{th} number is denoted by rₙ, n is a serial number, addressing ROM 1 by taking the high N₁ bits as address b₁ to obtain corresponding function value of cos(2πu₁) or sin(2πu₁), addressing ROM 2 by taking the low N₂ bits as address b₂ to obtain corresponding function value of \sqrt{−2 ln(u₂)}, where address bit-width N₁ of ROM 1 and address bit-width N₂ of ROM 2 satisfy the following constraints:
$$\{ \begin{matrix}{N}_{1} \geq ⌈ \frac{{N}_{D A C}}{2} ⌉ \\ {N}_{2} \geq ⌈ \frac{{N}_{D A C}}{2} ⌉\end{matrix}$$
where N_{DAC} is the bit-width of a DAC;
multiplying the function value of cos(2πu₁) or sin(2πu₁) by the function value of \sqrt{−2 ln(u₂)} to obtain a random number, which obeys standard Gaussian distribution and is denoted by xₙ;
then reading out the h^{th} plurality of parameters of Gaussian mixture model, namely the means μₖ^{h} and variances σₖ^{h}, k=1, 2, . . . , K, which correspond to the specific distribution of an arbitrary distribution noise to be generated, from the RAM for digital synthesis, where the k^{th} Gaussian noise signal is:
$${y}_{k n}^{h} = {σ}_{k}^{h} {x}_{n} + {μ}_{k}^{h}$$
where the multiplication operations and add operation are realized by Floating-point IP;
2.3). limiting amplitude
limiting the amplitude of the k^{th} Gaussian noise signal yₖₙ^{h}:
$${y}_{kn}^{h} = \{ \begin{matrix}{y}_{kn}^{h} , & {y}_{kn}^{h} ∈ [ {A}_{min} , {A}_{max} ] \\ {y}_{k ( n - 1 )}^{h} , & otherwise\end{matrix}$$
where yₖ₀^{h}=μₖ^{h};
2.4). normalizing
normalizing the k^{th} amplitude limited Gaussian noise signal yₖₙ^{h} to obtain the k^{th} Gaussian noise signal Dₖₙ^{h}:
$${D}_{k n}^{h} = ⌊ \frac{{y}_{k n}^{h} - {A}_{min}}{{A}_{max} - {A}_{min}} \cdot ( {2}^{{N}_{D A C}} - 1 ) ⌋ = ⌊ ( {y}_{k n}^{h} - offset ) \cdot gain ⌋$$
where parameters offset and gain are as follows:
$$offset = {A}_{min} , gain = \frac{{2}^{{N}_{DAC}} - 1}{{A}_{max} - {A}_{min}}$$
where parameters offset and gain are sent from the upper computer, and the data type of parameters offset and gain is double-precision floating point;
transforming the k^{th} Gaussian noise signal Dₖₙ^{h} into a fixed-point signal according to the bit-width N_{ADC} of the DAC;
2.5). outputting an analogy noise signal
successively inputting the K Gaussian noise signal Dₖₙ^{h}, k=1, 2, . . . , K to the DAC, which has one input and one output, to obtain an analogy signal, amplifying the obtained analogy signal Aₘₐₓ−Aₘᵢₙ times and setting bias voltage to Aₘᵢₙ to obtain an analogy noise signal with amplitude interval [Aₘᵢₙ, Aₘₐₓ], then outputting the analogy noise signal;
2.6). repeating step 2.2)˜step 2.5), when a next random number rₙ₊₁ is outputted, then an arbitrary distribution noise signal with specific distribution is outputted.

2. A method for real-time synthesizing an arbitrary distribution noise signal based on Gaussian mixture of claim 1, wherein in the process of executing Expectation Maximization algorithm to fit the distribution function ƒ(x), the K pairs of means and variances are spread out according to the range of number axis.

3. A method for real-time synthesizing an arbitrary distribution noise signal based on Gaussian mixture of claim 1, wherein the chaos model is a modulus 6-dimensional chaos model.
